(19) United States
(12) Patent Application Publication
(10) Pub. No.: US 2005/0118796 A1
(43) Pub. Date: Jun. 2, 2005

(54) Process for forming an electrically conductive interconnect

(76) Inventors: Stefanie R. Chiras, Peekskill, NY (US); Michael W. Lane, Cortlandt Manor, NY (US); Robert Rosenberg, Cortlandt Manor, NY (US); Terry A. Spooner, New Fairfield, CT (US)

Correspondence Address: CONNOLLY BOVE LODGE & HUTZ LLP, SUITE 800, 1990 M STREET NW, WASHINGTON, DC, 20036-3425, US

(21) Appl. No.: 10/722,558

(22) Filed: Nov. 28, 2003

(51) Int. Cl. H01L 21/4763; H01L 21/44

(52) U.S. Cl. 438/618

(57) ABSTRACT

An electrically conductive metallic interconnect in a trench or via in a dielectric is provided by depositing a first liner layer on the walls and bottom of the trench or via; removing residual contamination from the bottom of the trench or via; depositing a second liner layer in the trench; depositing a seed layer and filling the trench with electrically conductive metallic material.

### TECHNICAL FIELD

The present invention relates to a process for forming an electrically conductive metallic interconnect in a via in a dielectric. More particularly, the present relates to reducing field induced metal contamination of the dielectric and/or leakage failure of the metallic interconnect. The present invention is of especial significance when the dielectric is a low-k dielectric.

### BACKGROUND OF INVENTION

Copper is presently the preferred material choice for forming interconnects in integrated circuits. Copper replaced aluminum and AlCu alloys due to lower resistance and better resilience to electromigration. The advantage of copper metallization has been recognized by the entire semiconductor industry. Copper metallization has been the subject of extensive research documented by two entire issues of the Materials Research Society (MRS) Bulletin. One dedicated to academic research on the subject is MRS Bulletin, Vol. XVIII, No. 6 (June 1993) and the other dedicated to industrial research in MRS Bulletin, Vol. XIX, No. 8 (August 1994). A 1993 paper by Luther et al, “Planar Copper-Polyamide Back End of the Line Interconnection for ULSI Devices:, in Proc. IEEE VLSI Multitevel Interconnection Conference, Santa Clara, Calif., June 8-9, 1993, p. 15, describes the fabrication of copper chip interconnections with four levels of metallization.

However, since copper has a tendency when used in interconnect metallurgy to diffuse into surrounding dielectric materials such as silicon dioxide, encapsulation of the copper is essential. The encapsulation inhibits hiss diffusion. One widely suggested method of lining includes employing a conductive barrier layer along the sidewalls and bottom surface of a copper interconnect. Typical of such barrier layers are tantalurn, titanium, tungsten, and nitrides thereof. In many devices, multiple layers of different barrier materials are employed such as a combination of tantalum and tantalum nitride as described in U.S. Pat. No. 6,291,885 to Cabral et al, disclosure of which is incorporated herein by reference. Capping of the upper surface of a copper interconnect usually employs silicon nitride.

The tantalum employed is typically an alpha-phase tantalum layer, which besides acting as a barrier, also acts as a redundant current carrier layer to assist the main conductor copper in current distribution.

One technique employed to provide these structures involves a sacrificial liner process. This sacrificial liner process comprises first etching the via/trench and liner patterns in a low-k dielectric material into which a Cu dual damascene structure will be processed to connect to the previous line in the layer below. Next an adhesive liner layer such as TaN is deposited, followed by an etch such as an argon sputter etch to remove, for instance, the TaN at the bottom of the via and the top layer of the metal line in the metallization layer such as a copper line to form a clean contact. This is typically followed by a barrier layer such as tantalum layer being deposited, for instance, in an HCM magnetron sputter system. The barrier layer, e.g.-tantalum, is then subsequently sputter etched from the bottom of the via to leave the barrier layer remaining on the sidewalls of the trench/via or lines.

However, at the same time the Ar etch removes the TaN from the bottom of the line, or trench, it tends to pattern into the dielectric. When the Ta is subsequently deposited and sputter etched the bottom of the trenches are poorly covered such that the Cu that is later deposited is able to escape through the defected liner into the dielectric causing failure.

### SUMMARY OF INVENTION

The present invention relates to a process that makes it possible to reduce field induced metal contamination of dielectric by metallic interconnect in a via and/or leakage failure of the metallic interconnect. The present invention relates to a process for forming an electrically conductive metallic interconnect in a via in a dielectric.

The process comprises:
providing a dielectric layer on a substrate, wherein the substrate comprises electronically conductive lines,
forming a trench or via in the dielectric layer and exposing electrically conductive line in the substrate;
depositing a first liner layer on the walls and bottom of the trench or via;
removing residual contamination from the bottom of the trench or via;
depositing a second liner layer on the walls and bottom of the trench or via;
depositing a seed layer in the trench or via; and
filling the trench or via with electrically conductive material.

Another aspect of the present invention relates an electrically conductive metallic interconnect structure obtained by the above disclosed process.

A still further aspect of the present invention relates to an electrically conductive metallic interconnect in a via or trench in a via or trench in a dielectric which comprises:
a dielectric layer on a substrate;
an electrically conductive line in the substrate;
a via or trench in the dielectric layer;
liner located on the walls and bottom of the trench wherein the liner in the bottom of the trench or via comprises at least one member selected from the group consisting of Ta, W and Ti and which directly contacts the electrically conductive line; and
electrically conductive material above the liner and filling the trench.

Other objectives and advantages of the present invention will become readily apparent to those skilled in this art from the following detailed description, wherein it is shown and described only the preferred embodiments of the invention simply by way of illustration of the best mode contemplated of carrying out the invention. As will be realized, the invention is capable of other and different embodiments, and its several details are capable of modifications in various obvious respects, without departing from the invention. Accordingly, the description is to be regarded as illustrative in nature and not as restrictive.

### SUMMARY OF FIGURES

FIGS. 1-8 are schematic diagrams of the structure during various stages of the process of the present invention.

FIG. 9 is an electron microscope photograph of a filled trench according to a process not following the steps of the present invention.

FIG. 10 is an electron microscope photograph of a filled trench employing the process of the present invention.

### BEST AND VARIOUS MODES FOR CARRYING OUT INVENTION

In order to facilitate an understanding of the present invention, reference is made to the figures.

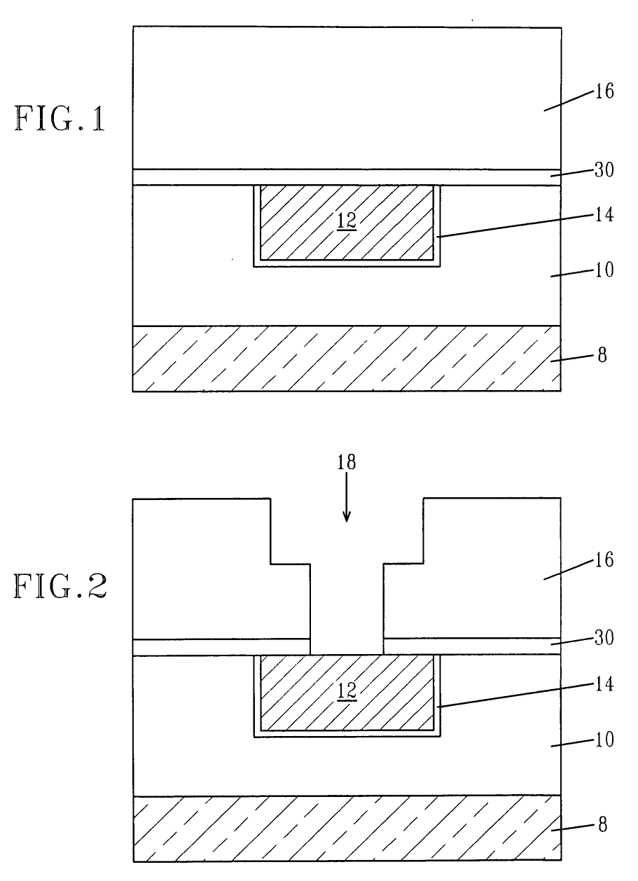

According to the present invention dielectric layers 10 and 16 are provided on a semiconductive substrate 8 such as silicon, silicon-germanium alloys, and silicon carbide or gallium arsenide. The dielectric layer 10 contains electrically conductive lines 12 and can contain a barrier or liner 14 on the bottom and sidewalls the conductive lines 12. Also, typically a capping layer 30 such as silicon nitride is provided on the conductive lines 12. See FIG. 1. Examples of dielectric layers 10 and 16 are silicon dioxide (SiO₂), phosphosilicate glass (PSG), boron doped PSG (BDPSG) or tetraethylorthosilicate (TEOS), and more typically low-k dielectrics having a dielectric constant of less than 3.9 such as SILK(available from Dow Chemical), SiCH(available from AMAT under the trade designation BLOK), SiCOH(available from Novellus under the trade designation Coral, from AMAT under the trade designation Black Diamond and from ASM under the trade designation Auora), SiCHN (available from IBM under the trade designation N Blok), CVD carbon-doped oxide, porous CVD carbon-doped oxide, porous and non-porous organo silicates, porous and non-porous organic spin-on polymers.

Typical conductive lines 12 are Cu, Al, and alloys thereof, and more typically Cu and Cu alloys. Liner materials 14 typically are Ta, W, Ti and nitrides thereof. A plurality of layers of different liner materials 14 can be employed, if desired.

A trench or via 18 is formed in dielectric 16 such as by etching, an example of which being reactive ion etching. The electrically conductive line 12 is also exposed by the etching. See FIG. 2.

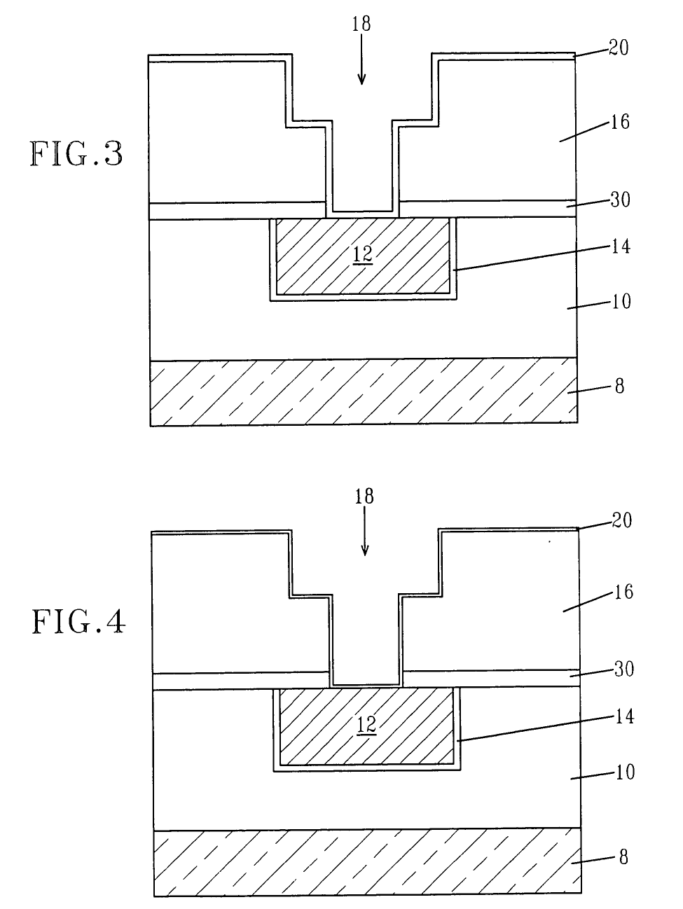

Next an adhesion liner layer 20 can optionally be deposited on the walls and bottom of the trench or via 18. See FIG. 3. Typical liner materials include nitrides of Ta, W and Ti. A plurality of layers of adhesion liner materials can be used if desired. The more typical adhesion liner 20 is TaN. The layer is typically about 80 to about 150 angstroms thick. This layer is employed to further enhance the adhesion between the conductive line to the dielectric and the subsequent to be deposited liner and also acts as a Cu diffusion barrier layer. This layer is typically deposited by means of physical vapor deposition, typically sputtering.

The layer 20 can be etched back in order to thicken the sidewalls of the trench 18. See FIG. 4. This etching back is typically carried out in the deposition chamber with an argon plasma using parameters that would tend to remove 0 to about 500 angstroms of oxide.

Residual contamination is removed from the bottom of the trench or via 18 by sputter etching such as employing argon sputter etching. See FIG. 5. The parameters of this argon sputter etching are typically the same as or similar to the argon sputter etching for the etching back step of FIG. 4 except that it is not carried out in the deposition chamber. The parameters are selected for typically removing 0 to about 500 angstroms of silicon dioxide.

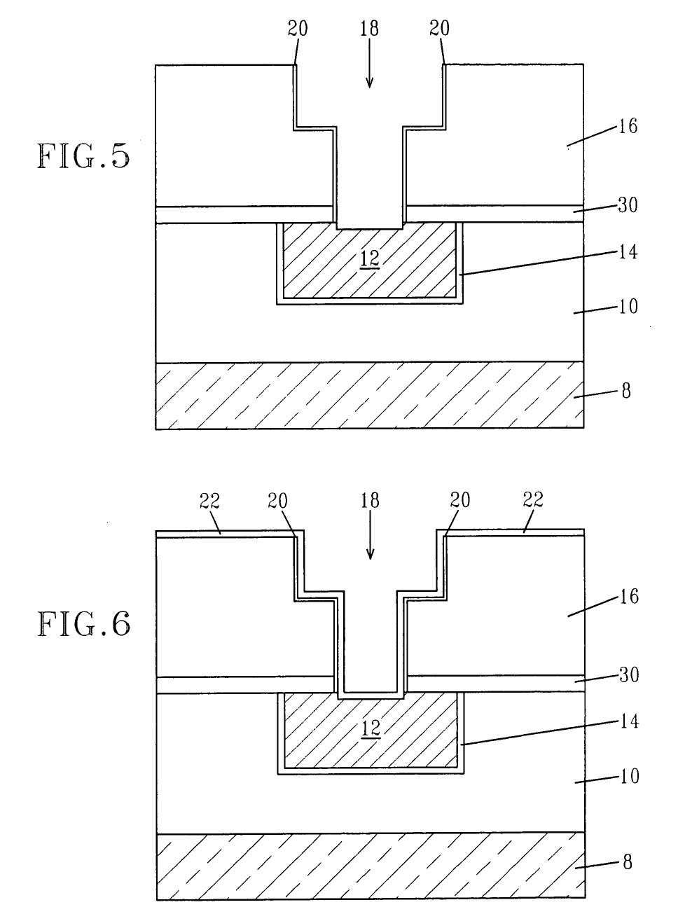

A liner layer 22 is deposited such as by employing an HCM(Hollow Cathode Magnetron) magnetron sputter system, such as available from Applied Materials under the trade designation “Endura”. See FIG. 6. Typical liner materials 22 include Ta, W and Ti and nitrides thereof A plurality of different liner materials can be used if desired. The more typical liner 22 material is Ta and even more typically alpha-phase Ta The liner layer 22 is typically about 20 to 200 angstroms thick and were typically about 80 to about 150 angstroms thick Processes for depositing the liner 22 are well known and need not be discussed in any detail herein. By way of example, Ta can be deposited such as by the technique disclosed in U.S. Pat. No. 6,399,258 B1, disclosure of which is incorporated herein by reference.

Typically, the sputter apparatus use a DC magnetron source configuration and use as the source of tantalum, tantalum having a purity of about 99.9% or greater. In carrying out the process, an inert gas such as argon at a flow rate of about 50 to about 130 standard cubic centimeters per minute (sccm) is injected into the process cavity which contains the target along with the wafer upon which the tantalum is to be deposited. The process cavity prior to injection of the inert gas was previously evacuated to a vacuum level of at least 1.0.×10 E6 torr using for example a cryogenic pump. Simultaneous to flowing the inert sputter gas, an additional gas flow of nitrogen is also begun at a flow rate of 20 to about 60 standard cubic centimeters per minute. The process cavity is filled with both gases to achieve an effective pressure of about 1 to about 10 million. The power typically employed to create a plasma for the purposes of the present invention is between about 0.4 and about 4.8 watts/square cm, and preferably about 1.6 to about 2.4 watts/square cm. Any combination of target voltage and current to achieve this power level can be employed. The material deposited is the highly oriented alpha-phase tantalum material of the present innovation. The deposition rate is typically about 1000 to about 2000 Å per minute and more typically about 1200 to about 1500 Å per minute.

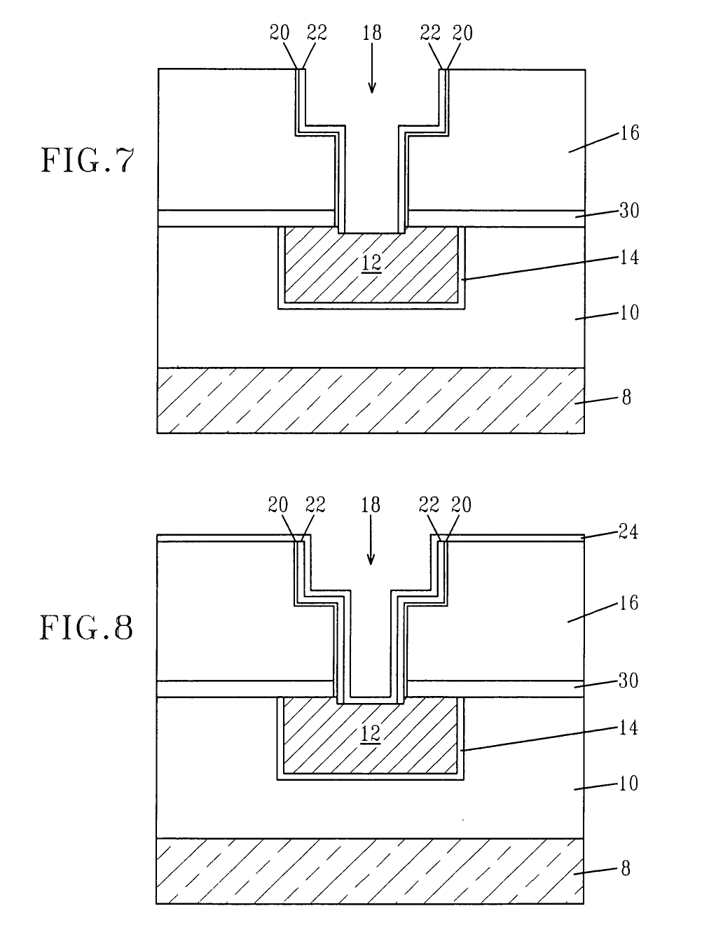

Residual contamination is next removed from the bottom of the trench or via 18 by sputter etching such as employing argon sputter etching. See FIG. 7. The sputter etching also tends to thicken the sidewalls of the trench or via 18. The etching can employ the same parameters as discussed above from removing contamination following the depositing of layer 20.

This sputter cleaning also results in removing liner 22 from the bottom of the via or trench 18 and sputtering of conductive material from conductive line 12.

According to the present invention, a second liner layer 24 is deposited on the walls and bottom of the trench or via 18. See FIG. 8. The liner layer 24 is typically Ta, W or Ti or nitrides thereof. A plurality of layers of different liner materials can be used for liner layer 24. More typically liner layer 24 is the same material as used for layer 22.

The process of the present invention makes it possible to provide a pure metal contact at the bottom of the via/trench or a Ta/Cu contact which is mechanically robust and tenaciously bonded. The process of the present invention also provides for a good diffusion barrier between the electrically conductive lives such as copper and the dielectric. In addition, the present invention makes it possible to have a liner on the sidewalls that differs from the liner at the bottom of the trench or via.

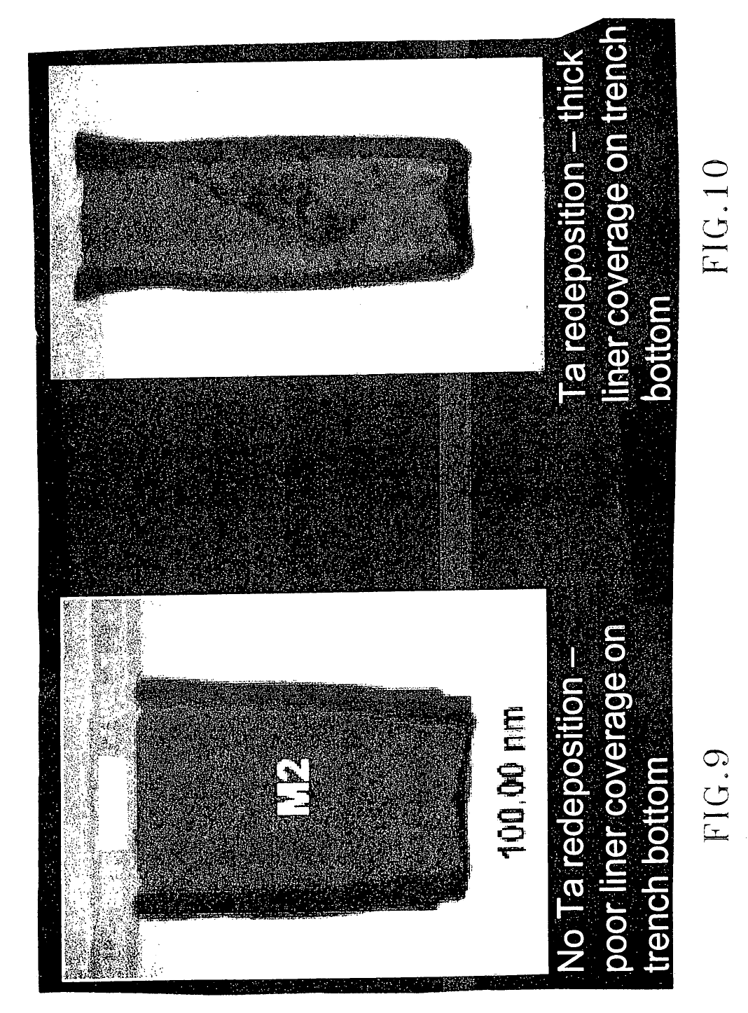

A comparison of FIGS. 9 and 10 illustrate advantages achieved by the present invention. FIG. 9, which differs from the present invention in not employing the step of depositing the second liner layer 22, illustrates poor liner coverage on the bottom of the trench or via. On the other hand, FIG. 10, which employs the processing of the present invention shows thick lines coverage on the bottom of the trench or via.

The structure can then be completed following processing known in the art. For instance, a copper seed layer can be deposited, followed by depositing copper to file the trench or via and then planarizing such as using chemical-mechanical processing (CMP).

All publications and patent applications cited in this specification are herein incorporated by reference, and for any and all purposes, as if each individual publication or patent application were specifically and individually indicated to be incorporated by reference.

The foregoing description of the invention illustrates and describes the present invention. Additionally, the disclosure shows and describes only the preferred embodiments of the invention but, as mentioned above, it is to be understood that the invention is capable of use in various other combinations, modifications, and environments and is capable of changes or modifications within the scope of the invention concept as expressed herein, commensurate with the above teachings and/or e skill or knowledge of the relevant art. The embodiments described hereinabove are further intended to explain best modes known of practicing the invention and to enable others skilled in the art to utilize the invention in such, or other, embodiments and with the various modifications required by the particular applications or uses of the invention. Accordingly, the description is not intended to limit the invention to the form disclosed herein. Also, it is intended tat the appended claims be construed to include alternative embodiments.

1. A process for forming an electrically conductive metallic interconnect in an via in a dielectric which comprises:
providing a dielectric layer in a substrate wherein the substrate comprises electrically conductive lines,
forming a trench or via in the dielectric layer and exposing electrically conductive line in the substrate;
depositing a first liner layer on the walls and bottom of the trench or via;
removing residual contamination from the bottom of the trench or via;
depositing a second liner layer on the walls and bottom of the trench or via;
depositing a seed layer in the trench or via and
filling the trench or via with electrically conductive material.

2. The process of claim 1 wherein the dielectric layer comprises a low-k dielectric having a dielectric constant of less than 3.9.

3. The process of claim 1 wherein the electrically conductive lines comprises copper, aluminum or alloy thereof.

4. The process of claim 1 wherein the electrically conductive lines comprise copper or alloy thereof.

5. The process of claim 1 wherein the first liner layer comprises at least one member selected from the group consisting of comprises n Ta, W, Ti, nitrides and combinations thereof.

6. The process of claim 1 wherein the first liner layer comprises Ta.

7. The process of claim 1 wherein the residual contamination is removed by etching.

8. The process of claim 7 wherein the etching comprises an argon etching.

9. The process of claim 1 wherein the second liner layer comprises at least one member selected from the group consisting of Ta, W, Ti, nitrides thereof and combinations thereof.

10. The process of claim 5 wherein the second liner layer comprises at least one member selected from the group consisting of Ta, W, Ti, nitrides thereof and combinations thereof.

11. The process of claim 1 wherein the second liner layer comprises Ta

12. The process of claim 6 wherein the second liner layer comprises Ta.

13. The process of claim 1 wherein the seed layer comprises copper.

14. The process of claim 1 wherein the conductive material for filling the trench or via comprises copper.

15. The process of claim 1 which further comprises depositing an adhesion liner layer prior to depositing the first liner layer.

16. The process of claim 15 wherein residual contamination is removed from the bottom of the trench or via prior to depositing the first liner layer.

17. The process of claim 15 wherein the adhesion liner layer comprises a nitride of Ta, W or Ti.

18. The process of claim 16 wherein the adhesion liner comprises TaN.

19. The process of claim 17 wherein the first liner layer comprises at least one member selected from the group consisting of comprises n Ta, W. Ti, nitrides and combinations thereof.

20. The process of claim 19 wherein the second liner layer comprises at least one member selected from the group consisting of Ta, W, Ti, nitrides thereof and combinations thereof.

21. The process of claim 18 wherein the first liner layer comprises Ta.

22. The process of claim 22 wherein the second liner layer comprises Ta.

23. The electrically conductive metallic interconnect obtained by the process of claim 1.

24. The electrically conductive metallic interconnect obtained by the process of claim 16.

25. An electrically conductive metallic interconnect in a via or trench in a via or trench in a dielectric which comprises
a dielectric layer on a substrate;
an electrically conductive line in the substrate;
a via or trench in the dielectric layer, liner located on the walls and bottom of the trench wherein the liner in the bottom of the trench or via comprises at least one member selected from the group consisting of Ta, W and Ti and which directly contacts the electrically conductive line; and
electrically conductive material above the liner and filling the trench.

26. The interconnect of claim 25 wherein the liner on the walls of the trench differs from that on the bottom.

27. The interconnect of claim 26 wherein the liner on the walls comprises at least one nitride of a member selected from the group consisting of Ta, W and Ti, and the liner at the bottom comprises at least one member selected from the group consisting of Ta, W and Ti.

28. The interconnect of claim 26 wherein the liner on the walls comprises TaN and the liner in the bottom comprises Ta.

29. The interconnect of claim 28 wherein the electrically conductive material comprises copper.

30. The interconnect of claim 27 wherein the electrically conductive material comprises copper.
